(19) United States
(12) Patent Application Publication
(10) Pub. No.: US 2015/0050602 A1
(43) Pub. Date: Feb. 19, 2015

(54) Spin Development Method and Apparatus

(71) Applicant: National Institute of Advanced Industrial Science and Technology, Chiyoda-ku, Tokyo (JP)

(72) Inventors: Sommawan Khumpuang, Tsukuba-shi (JP); Shiro Hara, Tsukuba-shi (JP)

(73) Assignee: National Institute of Advanced Industrial Science and Technology, Chiyoda-ku, Tokyo (JP)

(21) Appl. No.: 14/363,512

(22) PCT Filed: Oct. 3, 2012
(86) PCT No.: PCT/JP2012/075677

§ 371 Date: Jun. 6, 2014

(30) Foreign Application Priority Data
Dec. 6, 2011 (JP) 2011-267026

(51) Int. Cl. G03F 7/16; B05C 5/02; B05C 11/10; B05C 11/08

(52) U.S. Cl. CPC G03F 7/162; B05C 11/08; B05C 5/02; B05C 11/1005
USPC 430/434; 118/52

(57) ABSTRACT

An optimal development method and an apparatus of a resist formed on a half-inch size wafer. The development method is a development method of a resist formed on a wafer with a wafer size for manufacturing a number of minimized units of semiconductor devices. The method includes a first step, a second step, a third step, and a fourth step. The first step drops developer until a thickness of developer becomes maximum on the wafer whose rotation is stopped. The second step performs development while rotating the wafer. The third step supplies the developer about a half of the amount of developer of the first step on the wafer whose rotation is stopped. The fourth step performs development at a development period longer than the second step while rotating the wafer.

### TECHNICAL FIELD

The present invention relates to a spin development method and an apparatus that develop a resist formed on a wafer with extremely small area.

### BACKGROUND ART

In recent years, the manufacturing line for semiconductor devices includes a plurality of units called bays in which treatment apparatuses with the same type of functions are brought together within a vast clean room. A layout that employs a job-shop system has become mainstream. In the job-shop system, the bays are coupled together by a transfer robot and a belt conveyer.

As the workpiece treated in that manufacturing line, a wafer with a large diameter of, for example, 12 inches is used. In the production system, thousands of semiconductor chips are manufactured from one wafer.

However, with this job-shop system, in the case where a plurality of similar treatment processes are repeated, the conveyance within the bay or the conveyance distance between bays significantly increase in length, and the wait time increases. Thus, the manufacturing time increases. This causes a cost increase, for example, causes an increase in work in process. Therefore, the low productivity may become a problem as a manufacturing line for mass process of the workpieces.

Therefore, instead of the conventional manufacturing line in the job-shop system, a manufacturing line in a flow-shop system is also proposed. In this manufacturing line, semiconductor treatment apparatuses are arranged in the order corresponding to the treatment processes.

While this manufacturing line in the flow-shop system is optimal for manufacturing singular products in large quantities, it is necessary to rearrange the arrangement of the respective semiconductor treatment apparatuses in the manufacturing line in the order corresponding to the treatment flow of the workpiece in the case where the manufacturing procedure (recipe) needs to be changed due to a change of products. However, this rearrangement every time the products are changed is not realistic considering labor and time for the rearrangement. Especially, under the circumstances in which huge semiconductor treatment apparatuses are fixedly disposed within the closed space that is the clean room, it is realistically impossible to rearrange the semiconductor treatment apparatuses each time.

Further, in the conventional semiconductor manufacturing systems, since simultaneous productivity (production quantity per unit time) has been emphasized the most as a critical factor in order to minimize manufacturing costs, diameter scale-up in the workpiece size (silicon wafer size) and increase in the manufacturing unit count (number of orders with respect to a single product) have been given priority, pointing to gigantic manufacturing systems, megafab so to say.

In very large-scale manufacturing systems of this sort, the number of processes has exceeded several hundred, and in proportion to that, the number of bays and number of apparatuses have grown considerably.

Accordingly, although for that reason the throughput of the manufacturing lines as a whole has improved, constructing such megafab requires a facilities investment of several billion dollars, making the overall investment cost a huge sum.

Furthermore, along with such manufacturing systems going very large-scale, apparatus control grows complex and conveyance time and wait time in the conveyance system increase significantly. In response to this, the number of wafers in process that dwell along the production line also increases significantly. Since the unit cost of the large-diameter wafers employed here is extraordinarily high, increase in the number of works in process leads to elevation in costs.

Given these and other such circumstances, productivity as a whole, including facilities investment, is said to be currently turning in a decreasing direction compared with comparatively medium-scale manufacturing lines using wafers with diameters smaller than the current wafers.

Meanwhile, there is the need for manufacturing semiconductor in very small quantities, for example, several pieces to several hundreds of pieces in a manufacturing unit for engineer samples, ubiquitous sensors or a similar sensor.

Except this very large-scale manufacturing system, this ultra-small production can be carried out without having to sacrifice cost performance that much. However the very large-scale manufacturing system extremely reduces the cost performance for manufacturing semiconductor in very small quantities in the manufacturing line. Therefore, other kinds of products need to be manufactured in that manufacturing line at the same time.

However, when a wide variety of products are input at the same time for mixed production in that manner, the productivity of the manufacturing line further decreases with increasing number of types of products. As a result, in this very large-scale manufacturing system, very small-quantity production and multiproduct production cannot be appropriately managed.

Therefore, basically, one device is created from a 0.5-inch size wafer. Accordingly, the manufacturing processes employ a plurality of conveyable unit process apparatuses so as to facilitie rearrangement of the unit process apparatuses in a flow-shop and a job-shop, allowing appropriately handling very small-quantity production and multiproduct production. Such minimal fab system is proposed by the applicant (Japanese patent application No. 2010-195996).

Meanwhile, development systems of wafers in a device manufacturing process are also variously proposed (Non-Patent Literature 1).

### CITATION LIST

### Patent Literature

NON-PATENT LITERATURE 1: “Improved Resolution of Thick Film Resist (Effect of Development Technique)” Yoshihisa Sensu, et al. The Institute of Electronics, Information and Communication Engineers Journal, VOL. J86-C, No. 1, January 2003, p 50

### SUMMARY OF INVENTION

### Technical Problem

Among development methods described in Non-Patent Literature 1 (dipping development method, step puddle development method, vibration development method, reverse development method), the step puddle method (hereinafter referred to as an SP method), which is excellent in pattern resolution, was employed. Then, a resist of thickness 1 μm formed on a wafer of 4-inch diameter was actually developed.

Developer was supplied for five seconds while rotating the wafer at 100 rpm and a 20-second static development was performed. This operation was repeated by three times. An amount of used developer was 90 ml in total, and a development period was 60 seconds in total.

Thus, in the conventional method, the period required for developing the resist with 1-μm thickness was regarded as 60 to 300 seconds. Even the above-described SP method, which requires comparatively short development period, requires 60 seconds, thus not excellent in development efficiency. For example, the amount of used developer is the amount of developer to the extent that the entire wafer needs to be dipped, thus usage efficiency of developer is also not high.

According to Non-Patent Literature 1, the SP method employs the following development method. While rotating the wafer at 100 rpm, the developer is supplied on the wafer for five seconds. The static development is performed for 295 seconds. These operations are repeated three times. This method requires a comparatively long development period. In Non-Patent Literature 1, development characteristics in the above-described respective development methods were evaluated under a development period of 15 minutes. According to this evaluation, it is regarded that the SP method is excellent in development contrast. However, it is hard to say that the 15-minute development period is efficient development period.

Thus, these development methods are still not sufficient in terms of development efficiency and resolution as the development system of a resist on a workpiece of extremely minute size such as the above-described half-inch size.

The present invention has been made in view of the above-described actual situation, and its object is to provide an optimal development system that features excellent development efficiency, resource saving, and high resolution as the development system of a resist on an extremely minute workpiece such as a half-inch size applicable to the above-described minimal fab system or a similar system.

### Solution to Problem

In order to achieve the objects described above, the present invention is configured as follows. A spin development method that is a development method of a resist formed on a wafer with a wafer size for manufacturing a number of minimized units of semiconductor devices. The spin development method includes: a first step of: dropping a developer by an amount below an amount of spill over a stopped wafer and then rotating the wafer and dropping the developer until a thickness of the developer becomes almost maximum, or dropping a developer on a rotating wafer until a thickness of developer reaches almost maximum; and second step of performing development while rotating the wafer.

Additionally, the spin development method that is a development method of a resist formed on a wafer with a wafer size for manufacturing a number of minimized units of semiconductor devices. The spin development method includes: a first step of: dropping a developer by an amount below an amount of spill over a stopped wafer and then rotating the wafer and dropping the developer until a thickness of the developer becomes almost maximum, or dropping a developer on a rotating wafer until a thickness of developer reaches almost maximum; and a second step of performing development while rotating the wafer, a third step of dropping the developer about a half of the amount of the developer of the first step on the wafer rotated at a same rotation speed as the first step; and a fourth step of performing the development at a development period longer than the second step while rotating the wafer.

Additionally, the spin development method may be configured as follows. The wafer size is a 0.5-inch in diameter, an amount of developer to be dropped at the first step is approximately 0.4 ml, an amount of developer to be dropped at the third step is approximately 0.2 ml, a contact angle of the developer on the wafer during drop of the developer is approximately 135 to 146 degrees.

Additionally, the present invention is a spin developing apparatus of a resist formed on a wafer. The wafer has a wafer size for manufacturing a number of minimized units of semiconductor devices. The spin developing apparatus includes a rotating unit, a developer supply portion, a rotation controller, and a developer supply controller. The rotating unit is configured to rotate a wafer at a predetermined speed. The developer supply portion is configured to be able to drop a predetermined amount of developer on the wafer. The rotation controller is configured to control the rotation of the rotating unit. The developer supply controller is configured to: drop the developer by an amount below an amount of spill over a stopped wafer and then rotate the wafer and drop the developer until a thickness of the developer becomes almost maximum, or drop a developer on a rotating wafer until a thickness of the developer reaches almost maximum. Additionally, the developer supply portion includes a supply port height control mechanism configured to hold a distance between the wafer surface and the developer supply port of the developer supply portion to a distance at which consecutive droplet balls are formed between the developer supply port and the wafer surface.

Here, the number of minimized units is assumed that one piece of semiconductor device of 1 cm² is manufactured from a 0.5-inch size wafer as the exemplary embodiment of a semiconductor device of minimized unit. However, depending on a size of created device, though, the number of semiconductor devices is not limited to one, but the number of minimized units that can be created from one wafer may be equal to or more than two pieces.

### Advantageous Effects of Invention

With the present invention thus configured, an optimal development method and apparatus can be provided as a development method and an apparatus of a resist formed on a wafer with wafer size for manufacturing the number of minimized units of semiconductor devices. More specifically, together with improvement in development characteristics, reduction in an amount of developer and reduction in a development period are achieved. This allows improving production efficiency of throughput in all development processes including a supply of the developer, resist development, and drying of resist, and improving the quality.

### BRIEF DESCRIPTION OF DRAWINGS

FIG. 1 illustrates a developing apparatus according to an exemplary embodiment of the present invention.

FIG. 2 is a flowchart of the development method according to the exemplary embodiment of the present invention.

FIG. 3 is an explanatory view illustrating a development state corresponding to the development process in FIG. 2.

FIG. 4 is an explanatory view of an amount of developer supplied on a wafer.

FIG. 5 is an explanatory view illustrating a relationship between a contact angle of the developer on the wafer and a rotation speed of the wafer of the present invention.

FIG. 6 is an explanatory view of an amount of developer on the wafer of the present invention.

FIG. 7 is an explanatory view of how the developer is supplied in a conventional puddle development method.

FIG. 8 is a flowchart of the puddle development method and an SP development method using a conventional wafer of large diameter.

### DESCRIPTION OF EMBODIMENTS

The following describes an exemplary embodiment of the present invention by referring to the accompanying drawings.

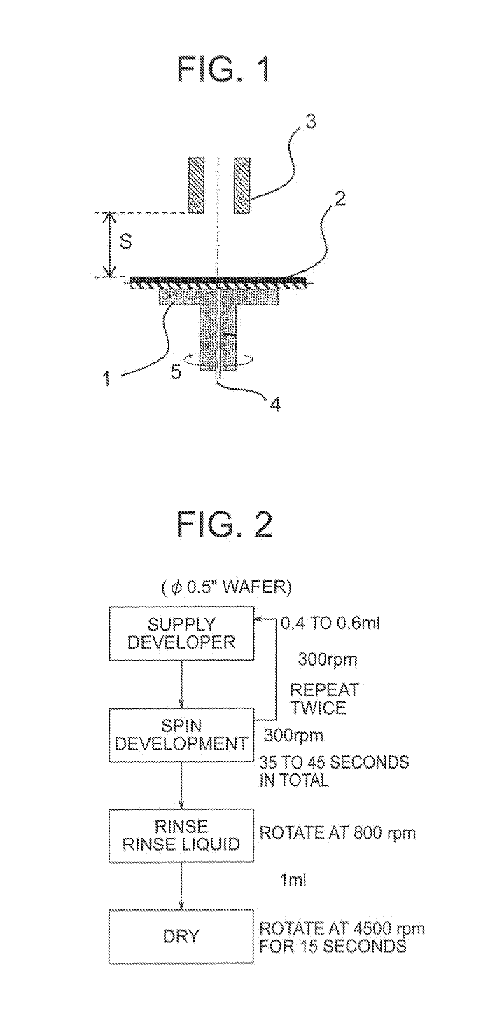

First, a developing apparatus used for the present invention is illustrated in FIG. 1. A wafer 2 of 0.5-inch size is placed on a work table 1 with a vacuum chuck 4. Air is suctioned from a vacuum chuck 4, and then a driving member (not illustrated) rotates the work table 1 in an arrow 5 direction. Accordingly, the work table 1 can be rotated while securing the placed wafer 2 on the work table 1. A supply nozzle (developer supply portion) 3, a supply nozzle (not illustrated), or a similar portion are selectively arranged right above a rotational center of the work table 1. The supply nozzle 3 is used to supply developer 6 on the wafer 2. The supply nozzle (not illustrated) is used to supply rinse on the wafer 2. Among the supply nozzles, the supply nozzle 3, which supplies the developer 6, has a supply port (developer supply port) with an inner diameter of 2 mm. A distance S from the wafer 2 to the supply port is designed to be 5 mm. A controller (not illustrated) is also disposed. The controller controls rotation of the work table 1 and controls an amount of supply from the supply nozzle 3.

The embodiment of the present invention used diazonaphthoquinone (DNQ) Novolac positive resist (i-ray resist) as a photosensitive resist formed on the wafer 2.

An application process of the resist was performed as follows. HMDS was heated to 90° C. for 10 seconds, spin-coated at 4000 rpm for 30 seconds, and then pre-baked at 90° C. for 60 seconds. Thus, a resist with film thickness of 600 to 700 nm was obtained.

The resist was exposed using i-ray LED light source with an amount of dose: 250 mJ/cm². Then, P.E.B was performed at 100° C. for 60 seconds.

Water containing TMAH (tetramethyl ammonium hydroxide) of available concentration of 2.38% was used as developer. An environmental temperature is 21° C.±1° C.

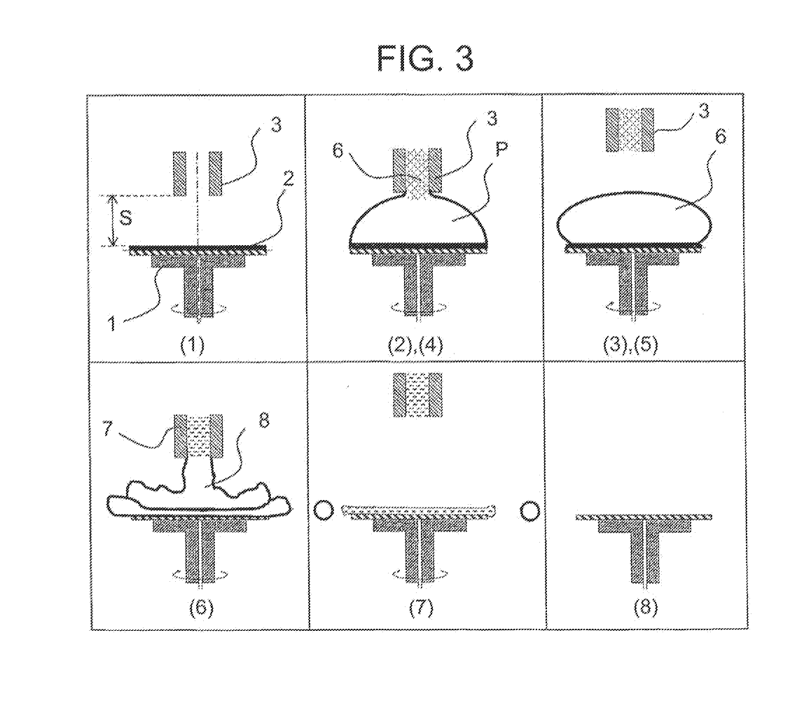

The following describes the development method of the present invention using FIG. 2 and FIG. 3.

A conveying device (not illustrated) conveys the wafer 2 of 0.5-inch size on the work table 1. The rotational centers are aligned to one another, and the wafer 2 is fixed on the work table 1 with the vacuum chuck 4.

### <First Step>

As illustrated in FIG. 3(1), the supply port of the supply nozzle 3 is arranged so that the distance S from a standby position to right above the rotational center of work table 1 becomes 5 mm (1).

Here, when the rotation speed of the work table 1 is set to 300 rpm, the developer 6 is supplied from the supply nozzle 3 on the wafer 2 by 0.4 ml. This amount of developer is an amount of liquid where a thickness of the developer 6 on the rotating wafer 2 becomes almost maximum. Alternatively, the developer 6 may be dropped by an amount below an amount of spill on a stopped wafer and then the wafer may be rotated while the developer may be dropped until reached to the amount. That is, the developer 6 is supplied on the rotating wafer 2 by the amount approximately corresponding to a maximum amount of liquid that can be placed (2).

In this respect, as illustrated in FIG. 3, the distance S is held between the supply port of the supply nozzle 3 and the surface of the wafer 2. The distance S is provided by, specifically 5 mm, so that consecutive droplet balls p is formed by surface tension.

### <Second Step>

With the rotation speed kept, the wafer 2 was developed for 15 seconds (first-time spin development) (3).

In this development, the supply port may be once evacuated. Alternately, the distance S during supply of the developer may be held. When the supply port is not evacuated, a position control of the supply nozzle 3 can be omitted. To evacuate, it is required to once lift the supply nozzle 3 with respect to the wafer 2 and then evacuate the supply port.

### <Third Step>

Next, with the rotation speed kept, the developer 6 was supplied from the supply nozzle 3 on the wafer 2 by 0.2 ml. The supply nozzle 3 is evacuated from the developer supply position. Specifically, the supply port is once lifted upward from the supply position and is returned to the standby position (4).

### <Fourth Step>

Next, with the rotation speed kept, the wafer 2 was developed for 20 seconds (second-time spin development) (5).

Thus, development was terminated by the above-described first step to fourth step.

### <Fifth Step>

Next, a rinse supply nozzle 7 is arranged at the rotational center. The rotation speed of the wafer 2 was increased to 800 rpm. Rinse liquid 8 (pre water) of 1 ml was supplied to rinse the wafer 2 for two seconds. This completely stops the development and removes a residual resist (6).

### <Sixth Step>

Next, the rotation speed was increased to 4500 rpm, and the wafer 2 was dried for 15 seconds. Thus, all development processes are terminated (7).

Finally, the rotation of the work table 1 is stopped to take out the wafer (8).

To perform the above-described development method, the embodiment of the present invention includes a rotating unit, the supply nozzle 3, a rotation controller, and a developer supply controller. The rotating unit is configured to rotate the wafer 2 at a predetermined speed. The supply nozzle 3 is configured to be able to drop a predetermined amount of developer on the wafer 2. The rotation controller is configured to control rotation of the rotating unit. The developer supply controller is configured to drop the developer by an amount below an amount of spill on the stopped wafer 2. Then, the developer supply controller is configured to rotate a wafer 2 and drop the developer until a thickness of the developer becomes almost maximum. Alternatively, the developer supply controller is configured to drop the developer on the rotating wafer 2 until the thickness of the developer reaches almost maximum.

Additionally, the supply nozzle 3 includes a supply port height control mechanism (not illustrated). The supply port height control mechanism is configured to hold a distance between the wafer 2 surface and a developer supply port to a distance at which the consecutive droplet balls p are formed between the developer supply port and the wafer surface.

Next, the following describes a development method compared with the embodiment and the evaluation result.

In the embodiment of the present invention, as described above, spin development and supply of the developer were performed twice for each. The total development period is 35 seconds.

In contrast to this, development patterns developed by a comparative example 1 [one-time spin development/no developer replacement, development period: 38 to 40 seconds] and a comparative example 2 [one-time static development/no developer replacement (namely, usual puddle development method), development period: 45 seconds] were compared with for evaluation.

The remaining resists were observed at resist lines with L & S width of 3 μm in both the comparative examples 1 and 2. The remaining resists were also observed at both mark widths of 2 μm and 5 μm in a cross-mark development pattern.

One extremely important gist in the spin development of the present invention is as follows. During dropping the developer, when a distal end of the supply nozzle is at comparatively upward of the wafer, a dropped droplet is accelerated due to gravitation, and therefore kinetic energy when the dropped droplet is in contact with the wafer becomes large. Accordingly, the surface tension of the wafer fails to hold the developer on the wafer, spilling the liquid from the wafer. This wastes the developer by the amount of spill. To prevent this, like the present invention, a mechanism to control a nozzle height so as to approach the distal end of the nozzle to the wafer as much as possible. Additionally, it is important to actually approach the nozzle to the wafer and then drop the developer. Thus, closing the nozzle and dropping the developer causes the droplet ball p (FIG. 3(2)) of the developer consequently formed on the wafer to be in contact with the nozzle.

Next, the following is important. To evacuate the nozzle to the standby position during the development, if the nozzle is evacuated horizontal to the wafer surface, the droplet is dragged, thus spilling the liquid from the wafer. To prevent this, first, the nozzle needs to be vertically pulled upward. Then, an operation to evacuate the nozzle to the standby position is conducted.

As described above, the nozzle always needs not to be evacuated during development, the nozzle may still touch the droplet during development. In the case, the development is progressed with nozzle in touch with the droplet. Thus, touching the nozzle to the droplet is one feature of the spin development.

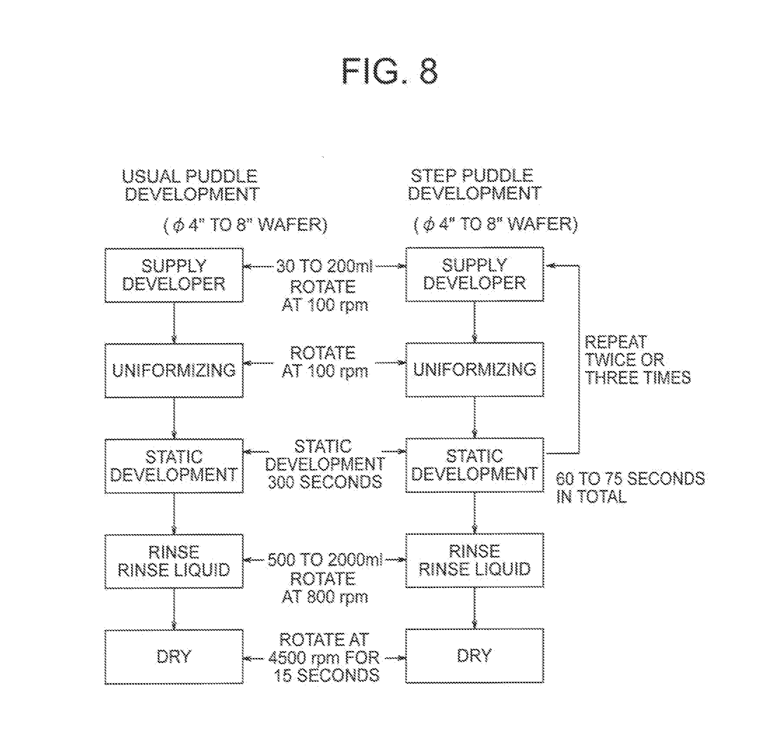

Next, the cases where the current wafers of four- to eight-inch sizes were developed by a usual puddle development method (one-time static development, no replacement of developer) or by the SP method (twice static developments, with replacement of developer) are illustrated in FIG. 8 for comparison with the exemplary embodiment.

As apparent from FIG. 8, the development period was 300 seconds in the usual puddle development method and was 60 to 70 seconds in the SP method. Both were longer than the development period of the exemplary embodiment (35 to 45 seconds). These development methods required 60 to 180 seconds for a rinse period while the exemplary embodiment requires only two seconds as described above. A drying period was approximately same (15 seconds) between these development methods and the development method of the exemplary embodiment. Accordingly, seeing the entire development process, development of large-diameter wafer by the conventional development method required 2.5 minutes to eight minutes. Meanwhile, development of 0.5-inch wafer by the method of the exemplary embodiment takes within a minute. Moreover, as described above, the development characteristics of the exemplary embodiment is more excellent than the conventional development characteristics.

An amount of developer required for the 4-inch wafer to be developed was 90 ml while, as described above, the development of the 0.5-inch wafer by the present invention was 0.6 ml. The area ratio of 0.5-inch diameter to the 4-inch diameter is 1:64. However, the amount of used developer was 1:150. Accordingly, the spin development method of the present invention can reduce the amount of used developer up to 1.5% with respect to the amount of used developer in the SP method.

Since a small-diameter wafer has a smaller area than the large-diameter wafer, a chip production quantity per unit time (throughput) is reduced. However, prices of apparatuses and costs taken for facilities investment for manufacturing apparatuses for small-diameter wafers and the factory systems are also reduced by the small diameter. Therefore, in principle, the cost of facilities investment/wafer area, which divides the cost of facilities investment by the wafer area, namely, investment productivity is not depend on the wafer diameter so much. In this respect, it can be said that the present invention, which brings great advantage with small-diameter wafers, is not inferior to a production method with large-diameter wafers. Additionally, the present invention can considerably save the developer. On the whole, it can be said that the present invention is a development method more advantageous than the conventional methods.

Thus, the following discusses a factor that this exemplary embodiment achieves the short development period and, moreover, short amount of developer.

### [Amount of Developer and Rotation Speed]

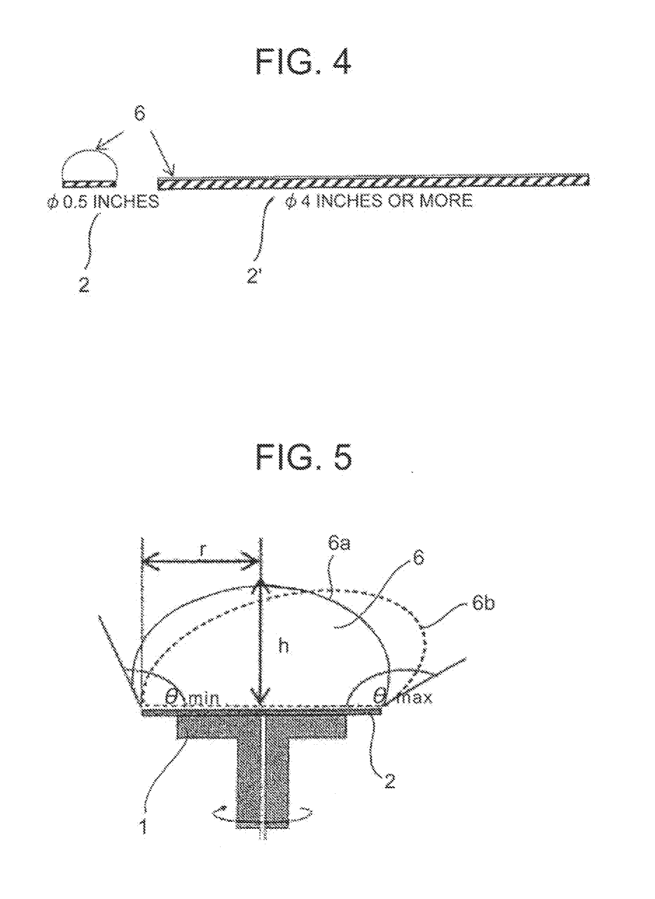

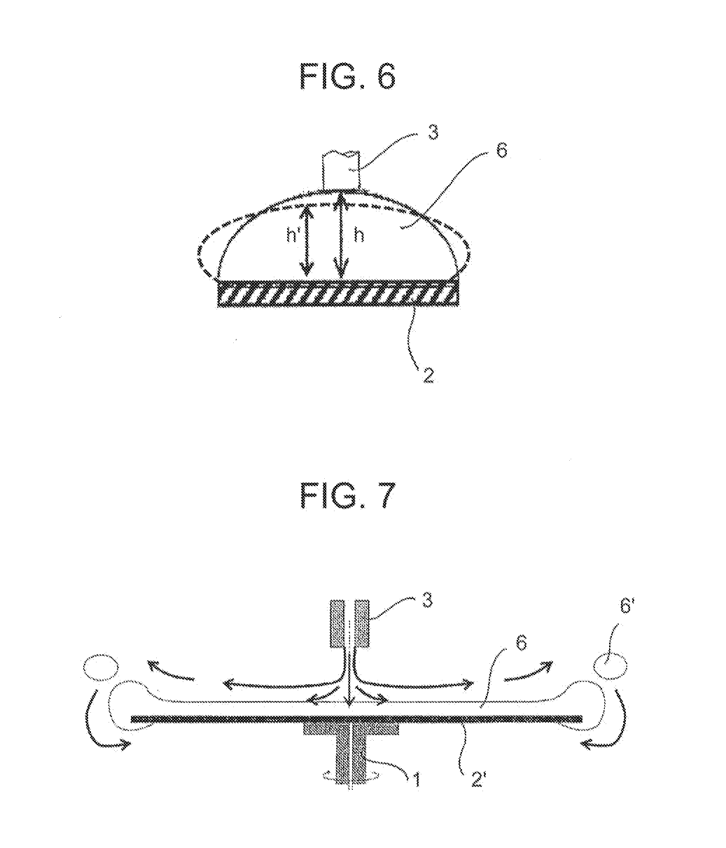

Regarding the developer held on the 4-inch size wafer illustrated in the right diagram of FIG. 4, an amount of held developer per unit area is less than an amount of held developer on the 0.5-inch size wafer illustrated in the left diagram for comparison. In the case of the 0.5-inch size wafer, when the developer is supplied during drop of the developer so that the droplet is not separated, the developer is held so as to be swollen from the entire surface of the wafer due to surface tension of developer. In contrast to this, if the surface area spreads like the 4-inch size wafer, the developer supplied on the wafer first becomes a lump due to the surface tension. If left as it is, the developer gradually spreads over the wafer surface; however, it takes several ten seconds for the developer to wholly spread. In the meantime, since development proceeds at a site to which the developer is supplied first, a development rate differs between a central portion and a peripheral edge portion. Accordingly, as illustrated in FIG. 6, in the case of the wafer with wide surface area, the developer needs to be supplied while rotating the wafer 2. In view of this, the developer 6 is thinly diffused from the wafer surface, dispersed from a wafer peripheral edge portion 2′. Consequently, compared with the 0.5 inch-size wafer, the amount of held developer per unit area becomes little.

Actually, in the case of this 4-inch wafer, rotation of the wafer at the rotation speed of 100 rpm requires several seconds for the developer 6 to spread over the entire surface. Moreover, the amount of used developer becomes 30 ml or more. The amount of held developer per unit area is 0.4 μl/mm².

In contrast to this, in the case of the 0.5-inch wafer, as illustrated in FIG. 3(2), (4), when the droplet is supplied during a drop of the developer so that the droplet is not separated, due to the surface tension, the developer is swollen from the entire wafer surface so as to hold a height (developer thickness) h (solid line portion in FIG. 5). Here, when the developer is supplied while the wafer itself is rotated at 300 rpm, as illustrated in FIG. 4, the developer receives centrifugal force and attempts to spread to the outward. Accordingly, a contact angle θ with the wafer surface becomes large. Then, in excess of the point at which the contact angle becomes the maximum (dashed line portion in FIG. 5), this centrifugal force increases more than the surface tension of the developer. Accordingly, the developer disperses outward due to the centrifugal force. Actually, this maximum contact angle (θmax) was 146° in this working example.

The amount of developer (developer thickness) and a wafer rotation speed are controlled until the developer on the wafer reaches the proximity of the maximum contact angle. Accordingly, as illustrated in FIG. 5 and FIG. 6, although a developer height h′ is shorter than the developer height h, which is supplied at a minimum contact angle (θmin), a large amount of developer can be held on the wafer. Actually, when the rotation speed and the amount of supplied developer (developer thickness) are controlled so that the contact angle is held at the proximity of 135° to 146°, preferably, 146°, the amount of developer on the wafer during rotation of the wafer became the maximum, and the amount of held developer per unit area became 4 μl/mm². This is the amount of developer per unit area more than the amount of developer per unit area of the four inch-wafer by approximately one digit. The larger the amount of developer, the less a concentration change of the developer caused by the resist melted in the developer. This ensures providing a wide margin for a development condition, which is advantageous. This decreases a risk of generating uneven development.

Thus, with this exemplary embodiment, the distance between the supply nozzle 3 and the wafer 2 is held to a gap of approximately 5 mm and the developer 6 of little amount of 0.4 ml is dropped so that the developer 6 is supplied forming the surface tension on the wafer (FIG. 3(2), (4)).

With the distance equal to or more than that, the droplet is separated during a drop. This makes supply of the maximum amount of liquid on the wafer difficult.

Moreover, unlike from the conventional puddle development methods, the developer is supplied while rotating the wafer. This allows supplying a large amount of developer on the wafer surface quickly, allowing efficient and effective use of the developer. This is a factor of ensuring high development efficiency and high reproducibility in this exemplary embodiment.

[Twice Puddle Developments and Amount of Developer]

As wettability of the developer and the wafer becomes better as an elapse of time, the developer supplied as described above is gradually dispersed from the wafer in association with the rotation of the wafer. N2 gas generated at a boundary between the developer and the resist surface as the development progresses is also carried to an outer periphery of the wafer in association with the rotation of the wafer. This quickly promotes the development, and a reaction rate of the developer at the first time is rapidly reduced.

Actually, the rotation speed was changed to 100 rpm, 200 rpm, and 300 rpm and the developed test patterns were inspected for comparison. If was found that the low speed required longer development period.

Accordingly, at the first-time puddle development, the developer is supposed to be required to be replaced at a faster timing. Accordingly, it is designed so as to meet the first-time development period<the second-time development period.

The second-time development period is set to the almost half of the first-time development period. This is due to the following reason. In association with the first-time development, wettability of the resist surface has been improved; therefore, a large amount of developer is not required like the first time. Actually, supply of the amount of developer like the first time is impossible.

Accordingly, in this exemplary embodiment, the amount of developer at the second-time puddle development can be less than the first-time puddle development, excellent in usage efficiency of developer.

As described above, the present invention achieves significantly excellent operation and effect in that the development efficiency, resolution reproducibility, or a similar factor as the resist development method for extremely small-sized wafers.

The rotation speed, the amount of developer (the developer thickness), and the contact angle may differ from the above-described exemplary embodiment depending on wettability of wafer and resist, viscosity of developer, resist film thickness, or a similar specification. However, the present invention can be modified without departing from the technical spirit of the above-described present invention.

### REFERENCE SIGNS LIST

1 work table
2, 2′ wafer
3 supply nozzle
6, 6′ developer
h, h′ developer height
θ contact angle

1. A spin development method that is a development method of a resist formed on a wafer with a wafer size for manufacturing a number of minimized units of semiconductor devices, the spin development method comprising:
a first step of: dropping a developer by an amount below an amount of spill over a stopped wafer and then rotating the wafer and dropping the developer until a thickness of the developer becomes almost maximum, or dropping a developer on a rotating wafer until a thickness of developer reaches almost maximum; and
a second step of performing development while rotating the wafer.

2. A spin development method that is a development method of a resist formed on a wafer with a wafer size for manufacturing a number of minimized units of semiconductor devices, the spin development method comprising:
a first step of: dropping a developer by an amount below an amount of spill over a stopped wafer and then rotating the wafer and dropping the developer until a thickness of the developer becomes almost maximum, or dropping a developer on a rotating wafer until a thickness of developer reaches almost maximum;
a second step of performing development while rotating the wafer;
a third step of dropping the developer about a half of the amount of the developer of the first step on the wafer rotated at a same rotation speed as the first step; and
a fourth step of performing the development at a development period longer than the second step while rotating the wafer.

3. The spin development method according to claim 2, wherein
the wafer size is a 0.5-inch in diameter, an amount of developer to be dropped at the first step is approximately 0.4 ml, an amount of developer to be dropped at the third step is approximately 0.2 ml, a contact angle of the developer on the wafer during drop of the developer is approximately 135 to 146 degrees.

4. A spin developing apparatus; comprising:
a rotating unit configured to rotate a wafer at a predetermined speed;
a developer supply portion configured to be able to drop a predetermined amount of developer on the wafer;
a rotation controller configured to control the rotation of the rotating unit; and
a developer supply controller configured to: drop the developer by an amount below an amount of spill over a stopped wafer and then rotate the wafer and drop the developer until a thickness of the developer becomes almost maximum, or drop a developer on a rotating wafer until a thickness of the developer reaches almost maximum.

5. The developing apparatus according to claim 4, wherein
the developer supply portion includes a supply port height control mechanism configured to hold a distance between the wafer surface and the developer supply port of the developer supply portion to a distance at which consecutive droplet balls are formed between the developer supply port and the wafer surface.
